(19) United States
(12) Patent Application Publication
(10) Pub. No.: US 2024/0365466 A1
(43) Pub. Date: Oct. 31, 2024

(54) VEHICULAR WIRING BOARD

(71) Applicant: YAZAKI CORPORATION, Tokyo (JP)

(72) Inventors: Hideaki Kikuchi, Susono-shi (JP); Hiroyuki Ogura, Susono-shi (JP)

(21) Appl. No.: 18/633,512

(22) Filed: Apr. 12, 2024

(30) Foreign Application Priority Data
Apr. 28, 2023 (JP) 2023-075007

(51) Int. Cl. H05K 1/02; B60R 16/02; B60R 16/023

(52) U.S. Cl. CPC H05K 1/0298; B60R 16/0215; B60R 16/0238; H05K 2201/0394

(57) ABSTRACT

A vehicular wiring board includes: a panel attached to a vehicle body and partitioning a vehicle interior and a front compartment of the vehicle body, an electric wiring disposed on a surface of the panel and integrated with the panel; and a box-shaped body disposed on the surface of the panel and integrated with the panel. The box-shaped body includes an electric circuit.

### CROSS-REFERENCE TO RELATED APPLICATION(S)

This application is based upon and claims the benefit of priority from prior Japanese patent application No. 2023-075007 filed on Apr. 28, 2023, the entire contents of which are incorporated herein by reference.

### BACKGROUND

### 1. Field of the Invention

The present disclosure relates to a vehicular wiring board.

### 2. Description of the Related Art

In a vehicle, various electronic devices are mounted on an instrument panel in front of a driver's seat and a passenger's seat in a vehicle interior. Accordingly, it is necessary to perform wiring of a path for supplying power from a power supply such as an in-vehicle battery to each electronic device, a path for inputting and outputting a signal required by each electronic device, and a path for communicating among a plurality of electronic devices. In general, a wire harness (wiring) to be connected to an electronic device is installed around the instrument panel.

Further, the instrument panel is provided with a reinforcing member called a “reinforcement” extending in a left-right direction. In the related art, a wire harness to be connected to an electronic device is supported by a reinforcement (JP2019-119287). Specifically, in the wire harness, a trunk line extending in the left-right direction is supported by the reinforcement, and branch lines branching from the trunk line extend downward and are connected to the electronic device.

However, since the wire harness provided with the plurality of branch lines has a complicated shape, it is necessary to manually assemble the wire harness to a vehicle, and there is a problem that assembly work becomes complicated.

### SUMMARY

The present disclosure has been made in view of the above circumstances, and an object thereof is to provide a vehicular wiring board that facilitates assembly work of wiring to the vicinity of an instrument panel.

The above object according to the present disclosure is achieved by the following configuration. Specifically, according to an aspect of the present disclosure, there is provided a vehicular wiring board including: a panel attached to a vehicle body and partitioning a vehicle interior and a front compartment of the vehicle body; an electric wiring disposed on a surface of the panel and integrated with the panel; and a box-shaped body disposed on the surface of the panel and integrated with the panel, where the box-shaped body includes an electric circuit.

According to the vehicular wiring board of the present disclosure, work for assembling the wiring such as a wire harness in the vicinity of the instrument panel can be facilitated. That is, since the electric wiring and the one or more box-shaped bodies are integrated with the panel, the number of branch lines of the wire harness connecting wiring on the panel and wiring on a vehicle body side is reduced, and it is easy to form a simple shape. Accordingly, wiring work and attachment of the wire harness are facilitated.

The present disclosure has been briefly described above. Further, details of the present disclosure can be clarified by reading modes (hereinafter, referred to as “embodiments”) for carrying out the disclosure described below with reference to the accompanying drawings.

### BRIEF DESCRIPTION OF THE DRAWINGS

The present disclosure will become more fully understood from the detailed description given hereinbelow and the accompanying drawing which is given by way of illustration only, and thus is not limitative of the present disclosure and wherein:

FIG. 1 is a perspective view showing an outline of an external appearance of a wiring board before box-shaped bodies are mounted;

FIG. 2 is a perspective view showing an outline of an external appearance of the wiring board after the box-shaped bodies are mounted;

FIG. 3 is a perspective view showing an outline of an external appearance of the wiring board mounted on a vehicle body;

FIG. 4 is a longitudinal cross-sectional view showing an example of a structure of connection portions between a resin panel and the box-shaped body; and

FIG. 5 is a longitudinal cross-sectional view showing an example of a structure of a connection portion between the wiring board and a vehicle body.

### DETAILED DESCRIPTION OF THE INVENTION

A specific embodiment of the present disclosure will be described below with reference to the drawings.

### <Description of Outline of Vehicular Wiring Board and Mounting Portion Thereof>

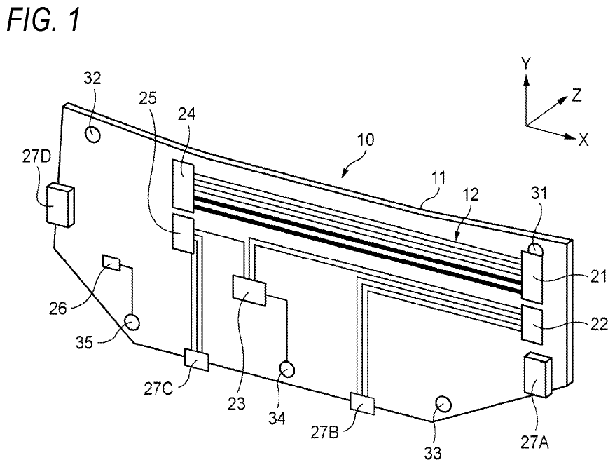

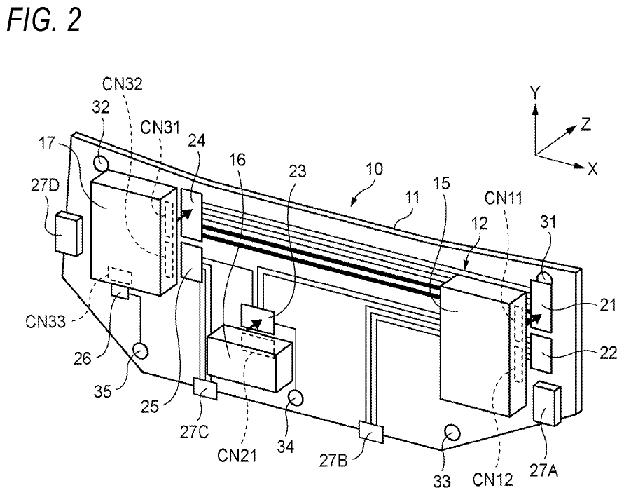

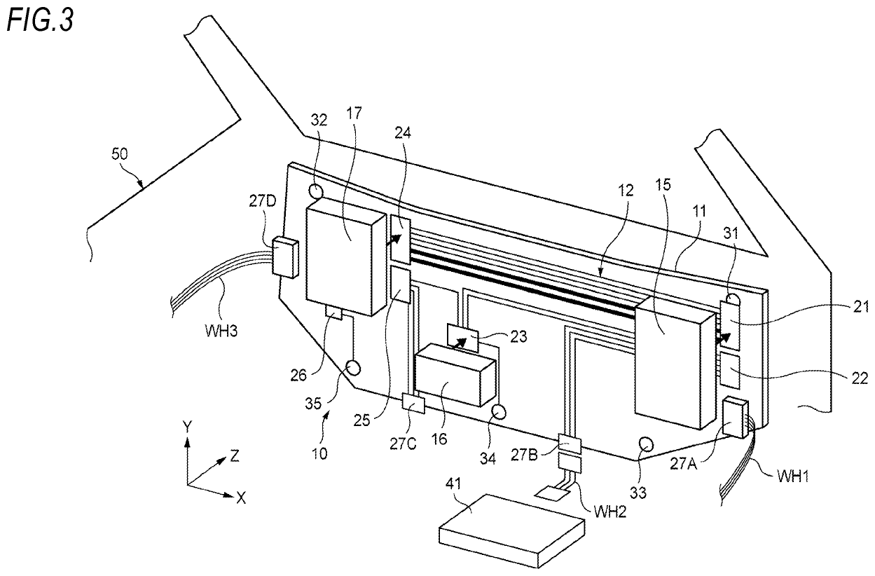

FIG. 1 shows an outline of an external appearance of the wiring board 10 before box-shaped bodies are mounted. FIG. 2 shows an outline of an external appearance of the wiring board 10 after box-shaped bodies 15, 16, and 17 are mounted. FIG. 3 shows an outline of an external appearance of the wiring board 10 mounted on a vehicle body 50. The wiring board 10 shown in FIGS. 1 to 3 corresponds to a vehicular wiring board of the present disclosure.

As shown in FIG. 3, the wiring board 10 is attached to the vehicle body 50 made of metal, and includes a resin panel 11 that partitions a vehicle interior in the vehicle body 50 and a front compartment provided in front of the vehicle interior, printed wiring 12 disposed on the resin panel 11, and one or more box-shaped bodies 15 to 17.

The printed wiring 12 and the box-shaped bodies 15 to 17 are fixed onto a surface of the resin panel 11 in advance, and are assembled to the vehicle body 50 as shown in FIG. 3 in a state of being integrated as the wiring board 10.

The printed wiring 12 is obtained by printing and fixing a thin metal wiring made of copper foil or the like onto the resin panel 11, and includes a plurality of power supply lines, ground lines, signal lines, communication lines, or the like independent for each system. That is, the printed wiring 12 on the resin panel 11 can perform an equivalent function to a general wire harness.

A surface of the printed wiring 12 is covered with a protective insulating sheath except for a part such as a terminal portion used for connection. For example, a flat cable (FC), a flexible flat cable (FFC), or a flexible printed circuit (FPC) may be fixed onto the resin panel 11 instead of the printed wiring 12. Further, a group of electric wires obtained by bundling a plurality of covered electric wires in an integrated manner, a plurality of covered electric wires arranged in parallel in a row, or a printed circuit body may be fixed onto the resin panel 11 in an integrated manner.

The box-shaped bodies 15 to 17 disposed on the resin panel 11 are electric junction boxes (J/Bs) or various electronic control units (ECUs) mounted inside a box-shaped housing. As shown in FIG. 2, the box-shaped bodies 15 to 17 of appropriate types are disposed on the resin panel 11 in accordance with specifications of a vehicle on which the wiring board 10 is mounted.

### <Description of Vehicle Body 50>

The vehicle body 50 to which the wiring board 10 of the present embodiment is attached is formed by casting with a large mold, for example.

The vehicle body 50 formed by casting with the large mold has high strength. Therefore, a partition wall between the vehicle interior and the front compartment does not need to have strength enough to maintain a shape of the vehicle body. Accordingly, the vehicle body 50 and the partition wall do not need to be integrally formed, and a separate partition wall can be adopted. In addition, in the case of an electric automobile on which no engine is mounted, no internal combustion engine is present, a high temperature is hardly generated, and noise is small. For this reason, not only metal but also a resin can be adopted as the partition wall in the vehicle body 50.

For the reasons described above, in the present embodiment, the wiring board 10 that is attached to the vehicle body 50, formed by casting, of the electric automobile on which no engine is mounted and that adopts the resin panel 11 as a main portion of the partition wall is exemplified.

A vehicle interior in which a driver's seat, a front passenger's seat, and a rear seat are disposed, and a front compartment provided in front of the vehicle interior are formed in the vehicle body 50. In the vehicle body 50, there is no partition wall between the vehicle interior and the front compartment, and an opening is provided. The resin panel 11 of the wiring board 10 is formed in a shape capable of reliably closing the opening in accordance with an opening shape between the vehicle interior and the front compartment.

### <Description of Printed Wiring 12 and Connectors>

In the example shown in FIG. 1, six surface mount connectors 21, 22, 23, 24, 25, and 26 are mounted on each portion of the surface of the resin panel 11. Four edge connectors 27A, 27B, 27C, and 27D are mounted on a peripheral edge portion of the resin panel 11.

Electrodes in the surface mount connector 21 and electrodes in the surface mount connector 24 are electrically connected to each other via several circuit patterns of the printed wiring 12 extending in an X-axis direction. For example, the electrodes of the surface mount connectors 21 and 24 are connected and fixed to portions such as exposed end portions of the circuit patterns of the printed wiring 12 by soldering.

Similarly, the surface mount connector 22 is electrically connected to the surface mount connector 23 and the edge connector 27B via several circuit patterns of the printed wiring 12 extending in the X-axis direction and a Y-axis direction. The surface mount connector 25 is electrically connected to the surface mount connector 23 and the edge connector 27C via several circuit patterns of the printed wiring 12 extending in the X-axis direction and the Y-axis direction.

Further, the surface mount connector 23 and a conductor of a wiring board fixing portion 34 and the surface mount connector 26 and a conductor of a wiring board fixing portion 35 are electrically connected to each other via the circuit pattern of the printed wiring 12.

The two edge connectors 27A, 27D, and the like can be electrically connected to each other on the surface of the resin panel 11 using wiring different from the printed wiring 12.

The example shown in FIG. 2 indicates that the box-shaped bodies 15, 16, and 17 are attached so as to be adhered to the surface of the resin panel 11 at predetermined places. Two connectors CN11 and CN12 are attached to a case back surface side (a surface facing the resin panel 11) of the box-shaped body 15 in an exposed state. Types, sizes, shapes, positions, and the like of the surface mount connector 21 and the connector CN11 are determined such that the surface mount connector 21 and the connector CN11 can be fitted to each other. Similarly, the types, sizes, shapes, positions, and the like of the surface mount connector 22 and the connector CN12 are determined such that the surface mount connector 22 and the connector CN12 can be fitted to each other.

Further, design and adjustment are performed in advance such that an interval at which and a direction in which the two adjacent surface mount connectors 21 and 22 are disposed coincide with an interval at which and a direction in which the two connectors CN11 and CN12 are disposed, respectively.

Accordingly, as shown in FIG. 2, the box-shaped body 15 is attached so as to be pressed against the surface of the resin panel 11 from a front side toward the surface mount connectors 21 and 22, and thus the box-shaped body 15 can be fixed at a predetermined position determined in advance, and connection work of an electric circuit is completed at the same time.

When mechanical strength is insufficient only by connecting the surface mount connectors 21 and 22 to the connectors CN11 and CN12, the box-shaped body 15 can be firmly fixed to the resin panel 11 by, for example, adhering a part of a back surface of the box-shaped body 15 to the surface of the resin panel 11 using a double-sided tape or the like.

Similarly to the above, the connector CN21 is attached to a case back surface side of the box-shaped body 16 in an exposed state. Types, sizes, shapes, positions, and the like of the surface mount connector 23 and the connector CN21 are determined such that the surface mount connector 23 and the connector CN21 can be fitted to each other.

Accordingly, as shown in FIG. 2, the box-shaped body 16 is attached so as to be pressed against the surface of the resin panel 11 from the front side toward the surface mount connector 23, so that the box-shaped body 16 can be fixed at a predetermined position determined in advance, and connection work of an electric circuit is completed at the same time.

Three connectors CN31, CN32, and CN33 are attached to a case back surface side of the box-shaped body 17 in an exposed state. Types, sizes, shapes, positions, and the like of the surface mount connector 24 and the connector CN31 are determined such that the surface mount connector 24 and the connector CN31 can be fitted to each other. Types, sizes, shapes, positions, and the like of the surface mount connector 25 and the connector CN32 are determined such that the surface mount connector 25 and the connector CN32 can be fitted to each other. Types, sizes, shapes, positions, and the like of the surface mount connector 26 and the connector CN33 are determined such that the surface mount connector 26 and the connector CN33 can be fitted to each other.

Further, design and adjustment are performed in advance such that intervals at which and a direction in which the three surface mount connectors 24, 25 and 26 are disposed coincide with intervals at which and a direction in which the three connectors CN31 to CN33 are disposed, respectively.

Accordingly, as shown in FIG. 2, the box-shaped body 17 is attached so as to be pressed against the surface of the resin panel 11 from the front side toward the surface mount connectors 24 to 26, so that the box-shaped body 17 can be fixed at a predetermined position determined in advance, and connection work of an electric circuit is completed at the same time.

### <Electric Connection Between Wiring Board 10 and Vehicle Body 50 Side>

In the example shown in FIG. 3, a connector of a sub-harness WH1 is connected to the edge connector 27A on a wiring board 10 side, a connector of a sub-harness WH2 is connected to the edge connector 27B, and a connector of a sub-harness WH3 is connected to the edge connector 27D. The sub-harnesses WH1 and WH3 are, for example, branch lines branching from a trunk line of a wire harness disposed on a vehicle body floor side. The sub-harness WH2 is a branch line prepared to connect a desired terminal device 41 to an electric circuit on the wiring board 10 side.

On the other hand, each of the surface mount connectors 23 and 26 and the connectors CN21 and CN33 shown in FIG. 2 includes a circuit of a body ground wire (GND). The body ground wire in the surface mount connector 23 is electrically connected to the conductor of the wiring board fixing portion 34 via the printed wiring 12. Similarly, the body ground wire in the surface mount connector 26 is electrically connected to the conductor of the wiring board fixing portion 35 via the printed wiring 12.

When the wiring board 10 is attached to the vehicle body 50 as shown in FIG. 3, each of the wiring board fixing portions 31 to 35 at five positions is fixed to a metal portion of the vehicle body 50 using bolts. Thus, when the wiring board 10 is attached to the vehicle body 50, the body ground wires in the surface mount connectors 23 and 26 are electrically connected to the vehicle body 50. That is, no special wiring work for connecting the body ground wires between the wiring board 10 and the vehicle body 50 is required, and no sub-harness of the body ground wire is required.

### <Description of Connection Portions Between Resin Panel 11 and Box-Shaped Body 15>

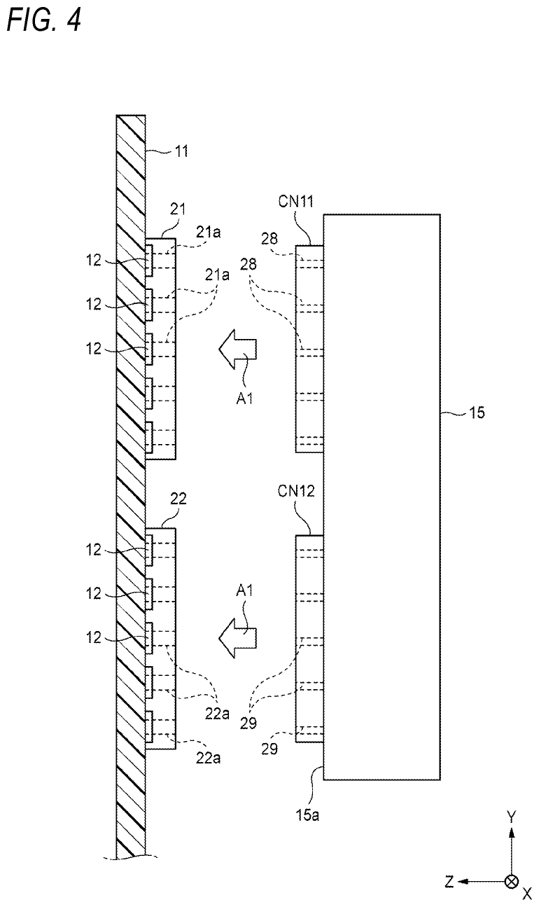

FIG. 4 shows an example of a structure of connection portions between the resin panel 11 and the box-shaped body 15.

As shown in FIG. 4, the surface mount connectors 21 and 22 are mounted on the surface of the resin panel 11, and metal terminals 21a and 22a are electrically connected to the printed wiring 12 on the surface of the resin panel 11.

The connectors CN11 and CN12 of the box-shaped body 15 are disposed in a state of being exposed to a case back surface 15a. Positions and the interval of the connectors CN11 and CN12 are adjusted in advance so as to coincide with those of the surface mount connectors 21 and 22 on a resin panel 11 side. Then, as shown in FIG. 4, when the box-shaped body 15 is pressed against a front surface side of the resin panel 11 in a state where the positions of the surface mount connectors 21 and 22 on the resin panel 11 and the positions of the connectors CN11 and CN12 on the box-shaped body 15 are aligned, the surface mount connectors 21 and 22 and the connectors CN11 and CN12 are fitted to each other, and the box-shaped body 15 is fixed onto the resin panel 11. At the same time, the metal terminals 28 in the connector CN11 are electrically connected to the metal terminals 21a in the surface mount connector 21, and the metal terminals 29 in the connector CN12 are electrically connected to the metal terminals 22a in the surface mount connector 22, respectively.

That is, the box-shaped body 15 can be adhered to a predetermined position on the resin panel 11 by attaching the box-shaped body 15 to the resin panel 11 in accordance with the positions of the surface mount connectors 21 and 22 on the resin panel 11. Further, since electric connection between the printed wiring 12 on the resin panel 11 and each circuit on the box-shaped body 15 is completed only by fitting the surface mount connectors 21 and 22 and the connectors CN11 and CN12 to each other, there is no need to prepare a special sub-harness for the electric connection, and work for connecting the sub-harness is also unnecessary.

Configuration may be changed such that the surface mount connectors 21 and 22 are connected to the connectors CN11 and CN12 via a cable (sub-harness) for relay. In this case, it is assumed to add a configuration for regulating a positional relationship between the resin panel 11 and the box-shaped body 15. For example, a projection is formed on one of the resin panel 11 and the box-shaped body 15, and an opening is formed on the other of the resin panel 11 and the box-shaped body 15, by fitting the projection and the opening to each other, a relative position can be regulated not to change. On the other hand, in the configuration of FIG. 4, since the mounting position of the box-shaped body 15 is regulated by the surface mount connectors 21 and 22 and the connectors CN11 and CN12, it is not necessary to provide a special projection or opening.

### <Description of Body Ground Connection Between Wiring Board 10 and Vehicle Body 50>

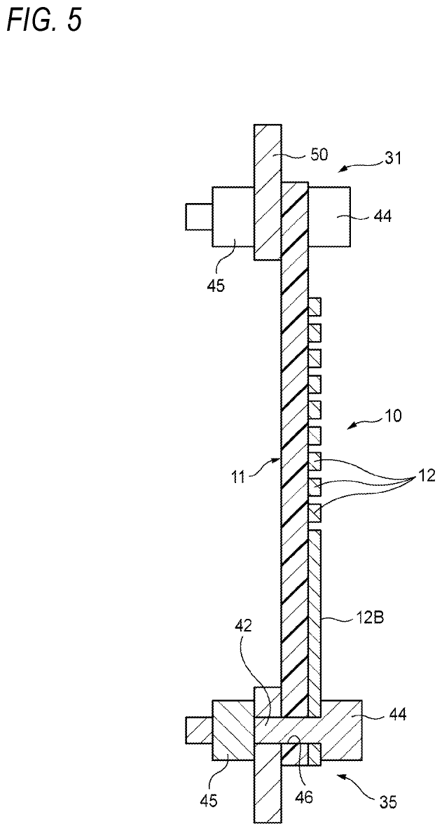

FIG. 5 shows an example of a structure of a connection portion between the wiring board 10 and the vehicle body 50.

At the positions of the wiring board fixing portions 31 to 35 of the wiring board 10 shown in FIG. 3, the wiring board 10 is fixed to the vehicle body 50 using bolts 44 and nuts 45 shown in FIG. 5. Further, at positions requiring body ground connection such as the wiring board fixing portions 34 and 35 in FIG. 3, a printed wiring 12B forming a body ground circuit is disposed at a position where the printed wiring 12B can come into contact with the bolt 44 (see FIG. 5).

Bolt through-holes 46 are formed in the positions of the wiring board fixing portions 31 to 35, respectively. Further, on a vehicle body 50 side, a bolt through-hole 42 is formed at a position corresponding to the bolt through-hole 46 of each of the wiring board fixing portions 31 to 35.

Accordingly, at the position of each of the wiring board fixing portions 31 to 35, the bolt 44 is inserted in a state where the bolt through-holes 46 and 42 are aligned as shown in FIG. 5, and the wiring board 10 can be fixed to the vehicle body 50 by screwing the bolt 44 and the nut 45.

Further, a metal (conductor) constituting the vehicle body 50 is exposed in the vicinity of the bolt through-hole 42. Therefore, for example, in the state shown in FIG. 5, the printed wiring 12B and the vehicle body 50 are electrically connected to each other via the bolt 44 made of metal (conductor) at the position of the wiring board fixing portion 35.

Accordingly, it is not necessary to prepare a special ground line for electrically connecting the wiring board 10 to the vehicle body 50, and work of connecting the ground line is also unnecessary.

According to the above-described embodiment, the wire harness can be easily assembled to the vicinity of the instrument panel only by attaching the wiring board 10 so as to close the opening between the vehicle interior and the front compartment. Further, by completing the attachment of box-shaped bodies such as the J/Bs and the various ECUs to the wiring board 10, the efficiency of attachment work is achieved. Since the resin panel 11 can be gripped by a robot hand, the wiring board 10 can also be automatically assembled to the vehicle body 50. Accordingly, the assembly work of the wire harness to the vicinity of the instrument panel is easily performed.

The present disclosure is not limited to the embodiment described above and can be appropriately modified, improved and the like. In addition, materials, shapes, sizes, numbers, arrangement positions and the like of components in the embodiment described above are freely selected and are not limited as long as the present disclosure can be implemented. For example, the material of the resin panel 11 is not limited to a resin, and may be metal or carbon.

The printed wiring 12 and the like can be formed not only on a surface on a vehicle interior side but also on a surface on a front compartment side on the resin panel 11. Alternatively, a metal foil similar to the printed wiring 12 may be printed on a wide area of one surface of the resin panel 11, and may be used as a ground electrode. The resin panel 11 may be provided in multiple layers, and the printed wiring 12 may be provided on both surfaces of each layer.

The edge connectors 27A to 27D in the above-described embodiment may be changed to surface mount connectors. Further, a through connector that penetrates the resin panel 11 may be adopted, and an electronic device disposed in the vehicle interior and an electronic device disposed in the front compartment may be connected to the through connector.

In a case where the wiring board 10 is attached to the vehicle body 50 of an automobile on which the engine is mounted, it is assumed that metal is used instead of the resin as the material of the resin panel 11. In the case of the automobile on which the engine is mounted, there is an internal combustion engine, and the temperature is likely to become high and noise is large. Therefore, from the viewpoint of safety and comfort, metal is adopted as the partition wall between the vehicle interior and the front compartment. Accordingly, it may be desirable to use metal as the material of the wiring board 10.

Here, features of the vehicular wiring board according to the embodiment of the present disclosure described above are briefly summarized and listed in the following [1] to [5].

[1] A vehicular wiring board (a wiring board 10) includes:
a panel (a resin panel 11) attached to a vehicle body (50) and partitioning a vehicle interior and a front compartment of the vehicle body;
an electric wiring (a printed wiring 12) disposed on a surface of the panel and integrated with the panel; and
a box-shaped body (15 to 17) disposed on the surface of the panel and integrated with the panel, in which
the box-shaped body includes an electric circuit.

According to the vehicular wiring board having the configuration of the above [1], the box-shaped bodies such as J/Bs or various ECUs can be integrated on the panel, which is useful for simplifying the configuration of a wire harness for connecting the box-shaped bodies to an external circuit. Further, work of attaching each box-shaped body and work of connecting each box-shaped body to the external circuit are also facilitated.

[2] The vehicular wiring board according to the above [1], in which
the box-shaped body is fixed to the panel in a state where a part of the box-shaped body overlaps a surface of a part of the electric wiring (surface mount connectors 21 to 26) (see FIG. 4).

According to the vehicular wiring board having the configuration of the above [2], it is easy to directly connect an electric circuit on the panel and the electric circuit of the box-shaped body without using a cable for relay or the like. As a result, it is possible to reduce the number of components such as electric wires and simplify attachment work.

[3] The vehicular wiring board according to the above [1] or [2], in which
the electric wiring includes a first terminal portion (at least one of the surface mount connectors 21 to 26) including a conductor exposed on a surface,
the box-shaped body includes a second terminal portion (at least one of connectors CN11, CN12, CN21, CN31, CN32, and CN33) including a conductor exposed on a surface facing the first terminal portion, and
the first terminal portion and the second terminal portion are electrically connected in a state where the box-shaped body overlaps the electric wiring and is fixed to the panel.

According to the vehicular wiring board having the configuration of the above [3], circuit connection between the electric circuit of the box-shaped body and an electric circuit on the panel can be implemented only by mounting the box-shaped body on the panel. Accordingly, it is possible to simplify work of the circuit connection accompanying the attachment of the box-shaped body.

[4] The vehicular wiring board according to any one of the above [1] to [3], in which
the panel includes a position determining portion (at least one of the surface mount connectors 21 to 26) configured to regulate an attachment position of the box-shaped body.

According to the vehicular wiring board having the configuration of the above [4], it is possible to suppress the occurrence of variation in the attachment position of the box-shaped body on the panel. Accordingly, the efficiency of work of attaching the box-shaped body to the panel can be improved.

[5] The vehicular wiring board according to any one of the above [1] to [4], further includes:
a conductive fixing portion (wiring board fixing portions 34 and 35) configured to attach the panel to the vehicle body, in which
the electric wiring and the box-shaped body each have a body ground wire, and
the body ground wire of the box-shaped body is electrically connected to the body ground of the vehicle body via the electric wiring on the panel and the fixing portion.

According to the vehicular wiring board having the configuration of the above [5], even when the panel is made of an electrically insulating material such as a resin, the electric connection of the body ground can be completed only by attaching the panel to the vehicle body. Therefore, work associated with the electric connection can be simplified.

1. A vehicular wiring board comprising:
a panel attached to a vehicle body and partitioning a vehicle interior and a front compartment of the vehicle body;
an electric wiring disposed on a surface of the panel and integrated with the panel; and
a box-shaped body disposed on the surface of the panel and integrated with the panel, wherein
the box-shaped body includes an electric circuit.

2. The vehicular wiring board according to claim 1, wherein
the box-shaped body is fixed to the panel in a state where a part of the box-shaped body overlaps a surface of a part of the electric wiring.

3. The vehicular wiring board according to claim 1, wherein
the electric wiring includes a first terminal portion including a conductor exposed on a surface,
the box-shaped body includes a second terminal portion including a conductor exposed on a surface facing the first terminal portion, and
the first terminal portion and the second terminal portion are electrically connected in a state where the box-shaped body overlaps the electric wiring and is fixed to the panel.

4. The vehicular wiring board according to claim 1, wherein
the panel includes a position determining portion configured to regulate an attachment position of the box-shaped body.

5. The vehicular wiring board according to claim 1, further comprising:
a conductive fixing portion configured to attach the panel to the vehicle body, wherein
the electric wiring and the box-shaped body each have a body ground wire, and
the body ground wire of the box-shaped body is electrically connected to the body ground of the vehicle body via the electric wiring on the panel and the fixing portion.
